(19) United States
(12) Patent Application Publication
(10) Pub. No.: US 2012/0306491 A1
(43) Pub. Date: Dec. 6, 2012

(54) MAGNETIC BALANCE TYPE CURRENT SENSOR

(75) Inventors: Yosuke IDE, Niigata-ken (JP); Masamichi SAITO, Niigata-ken (JP); Akira TAKAHASHI, Niigata-ken (JP); Kenichi ICHINOHE, Niigata-ken (JP)

(73) Assignee: ALPS GREEN DEVICES CO., LTD., Tokyo (JP)

(21) Appl. No.: 13/587,819

(22) Filed: Aug. 16, 2012

Related U.S. Application Data
(63) Continuation of application No. PCT/JP2011/054082, filed on Feb. 24, 2011.

(30) Foreign Application Priority Data
Mar. 12, 2010 (JP) 2010-056153

(51) Int. Cl. G01R 33/09

(52) U.S. Cl. 324/252

(57) ABSTRACT

A magnetic balance type current sensor of the present invention includes a magnetic field detection bridge circuit including four magnetoresistance effect elements whose resistance values change owing to application of an induction magnetic field from a current to be measured. Each of the four magnetoresistance effect elements includes a ferromagnetic fixed layer formed by causing a first ferromagnetic film and a second ferromagnetic film to be antiferromagnetically coupled to each other via an antiparallel coupling film, a non-magnetic intermediate layer, and a soft magnetic free layer. The first and second ferromagnetic films are approximately equal in Curie temperature to each other, a difference in magnetization amount therebetween is substantially zero, and the magnetization directions of the ferromagnetic fixed layers of three magnetoresistance effect elements are different by 180 degrees from the magnetization direction of the ferromagnetic fixed layer of the remaining one magnetoresistance effect element.

### CLAIM OF PRIORITY

This application is a Continuation of International Application No. PCT/JP2011/054082 filed on Feb. 24, 2011, which claims benefit of Japanese Patent Application No. 2010-056153 filed on Mar. 12, 2010. The entire contents of each application noted above are hereby incorporated by reference.

### BACKGROUND OF THE INVENTION

1. Field of the Invention

The present invention relates to a magnetic balance type current sensor utilizing a magnetoresistance effect element (TMR element or GMR element).

2. Description of the Related Art

In an electric vehicle, a motor is driven using electricity generated by an engine, and the intensity of the current for driving the motor is detected by, for example, a current sensor. The current sensor includes a magnetic core disposed around a conductor and having a cutaway portion (core gap) formed at a portion thereof, and a magnetic detecting element disposed within the core gap.

As the magnetic detecting element of the current sensor, a magnetoresistance effect element (GMR element or TMR element) including a laminate structure having a fixed magnetic layer with a fixed magnetization direction, a non-magnetic layer, and a free magnetic layer with a magnetization direction varying with respect to an external magnetic field, or the like is used. In such a current sensor, a full-bridge circuit is configured using a magnetoresistance effect element and a fixed resistance element. Such a technique is disclosed in Japanese Unexamined Patent Application Publication No. 2007-248054.

### SUMMARY OF THE INVENTION

When a full-bridge circuit is configured using a magnetoresistance effect element and a fixed resistance element, since the film configuration of the magnetoresistance effect element and the film configuration of the fixed resistance element are different from each other, a zero magnetizing field resistance value (R₀) or a temperature coefficient resistivity (TCR₀) in a zero magnetizing field differs between the magnetoresistance effect element and the fixed resistance element. Therefore, there occurs a problem that a midpoint potential serving as the output of the bridge circuit fluctuates owing to a temperature change and it is difficult to perform current measurement with a high degree of accuracy.

In view of the above-mentioned point, the present invention is made and provides a magnetic balance type current sensor capable of reducing a gap in a zero magnetizing field resistance value (R0) or a temperature coefficient resistivity (TCR0) between elements and performing the current measurement with a high degree of accuracy.

A magnetic balance type current sensor of the present invention includes a magnetic field detection bridge circuit configured to include four magnetoresistance effect elements whose resistance values change owing to application of an induction magnetic field from a current to be measured and provide two outputs for causing a voltage difference according to the induction magnetic field, a feedback coil configured to be disposed near the magnetoresistance effect element and generate a cancelling magnetic field for cancelling out the induction magnetic field, and a magnetic shield configured to attenuate the induction magnetic field and enhance the cancelling magnetic field, wherein the current to be measured is measured on the basis of a current flowing in the feedback coil when the feedback coil has been energized owing to the voltage difference and an equilibrium state where the induction magnetic field and the cancelling magnetic field cancel each other out has occurred, and each of the four magnetoresistance effect elements includes a self-pinned type ferromagnetic fixed layer configured to be formed by causing a first ferromagnetic film and a second ferromagnetic film to be antiferromagnetically coupled to each other via an antiparallel coupling film, a non-magnetic intermediate layer, and a soft magnetic free layer, wherein the first ferromagnetic film and the second ferromagnetic film are approximately equal in Curie temperature to each other, a difference in magnetization amount therebetween is substantially zero, the magnetization directions of the ferromagnetic fixed layers of three magnetoresistance effect elements from among the four magnetoresistance effect elements are equal to one another, and the magnetization direction of the ferromagnetic fixed layer of the remaining one magnetoresistance effect element is a direction different by 180 degrees from the magnetization directions of the ferromagnetic fixed layers of the three magnetoresistance effect elements.

According to the configuration, since the magnetic detecting bridge circuit is configured using the four magnetoresistance effect elements whose film configurations are equal to one another, it may be possible to reduce a gap in a zero magnetizing field resistance value (R0) or a temperature coefficient resistivity (TCR0) between elements. Therefore, it may be possible to reduce a variation in a midpoint potential independently of an ambient temperature and perform current measurement with a high degree of accuracy.

In the magnetic balance type current sensor of the present invention, it is desirable that the feedback coil, the magnetic shield, and the magnetic field detection bridge circuit are formed on a same substrate.

In the magnetic balance type current sensor of the present invention, it is desirable that the feedback coil is disposed between the magnetic shield and the magnetic field detection bridge circuit and the magnetic shield is disposed on a side near the current to be measured.

In the magnetic balance type current sensor of the present invention, it is desirable that each of the four magnetoresistance effect elements has a shape in which a plurality of belt-like elongated patterns, disposed so that longitudinal directions thereof are parallel to one another, are folded and the induction magnetic field and the cancelling magnetic field are applied so as to be headed in a direction perpendicular to the longitudinal direction.

In the magnetic balance type current sensor of the present invention, it is desirable that the first ferromagnetic film is formed using CoFe alloy including Fe of 40 atomic percent to 80 atomic percent and the second ferromagnetic film is formed using CoFe alloy including Fe of 0 atomic percent to 40 atomic percent.

In the magnetic balance type current sensor of the present invention, it is desirable that the magnetic shield is formed using a high magnetic permeability material selected from a group including an amorphous magnetic material, a permalloy-based magnetic material, and an iron-based microcrystalline material.

### BRIEF DESCRIPTION OF THE DRAWINGS

FIG. 1 is a diagram illustrating a magnetic balance type current sensor according to an embodiment of the present invention;

FIG. 2 is a diagram illustrating a magnetic balance type current sensor according to an embodiment of the present invention;

FIG. 3 is a cross-sectional view illustrating the magnetic balance type current sensor illustrated in FIG. 1;

FIG. 4 is a diagram illustrating a magnetic detecting bridge circuit in a magnetic balance type current sensor according to an embodiment of the present invention;

FIG. 5 is a diagram illustrating a current measurement state of the magnetic balance type current sensor illustrated in FIG. 2;

FIG. 6 is a diagram illustrating a magnetic detecting bridge circuit in the magnetic balance type current sensor illustrated in FIG. 5;

FIG. 7 is a diagram illustrating a current measurement state of the magnetic balance type current sensor illustrated in FIG. 2;

FIG. 8 is a diagram illustrating a magnetic detecting bridge circuit in the magnetic balance type current sensor illustrated in FIG. 7;

FIG. 9 is a diagram illustrating an R-H curved line of a magnetoresistance effect element in a magnetic balance type current sensor according to an embodiment of the present invention;

FIGS. 10A to 10C are diagrams for explaining a manufacturing method for a magnetoresistance effect element in a magnetic balance type current sensor according to an embodiment of the present invention; and

FIGS. 11A to 11C are diagrams for explaining a manufacturing method for a magnetoresistance effect element in a magnetic balance type current sensor according to an embodiment of the present invention.

### DESCRIPTION OF THE PREFERRED EMBODIMENTS

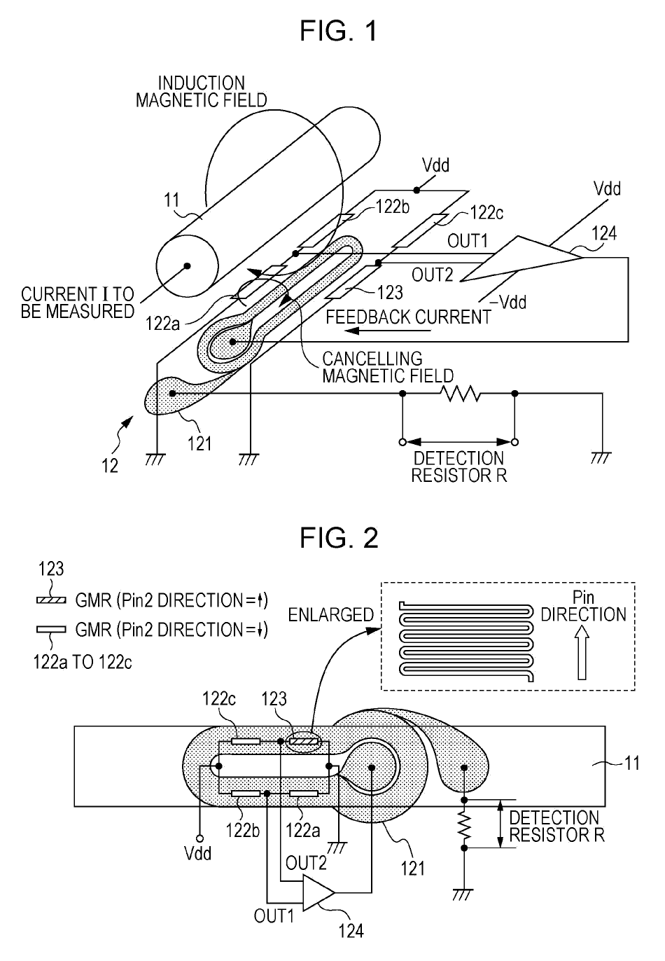

Hereinafter, embodiments of the present invention will be described in detail with reference to accompanying drawings. FIG. 1 and FIG. 2 are diagrams illustrating a magnetic balance type current sensor according to an embodiment of the present invention. In the present embodiment, the magnetic balance type current sensor illustrated in FIG. 1 and FIG. 2 is installed adjacent to a conductor 11 in which a current I to be measured flows. The magnetic balance type current sensor includes a feedback circuit 12 for causing a magnetic field (cancelling magnetic field) for cancelling out an induction magnetic field due to the current I to be measured which flows in the conductor 11. The feedback circuit 12 has a feedback coil 121, wound in a direction for cancelling out a magnetic field generated owing to the current I to be measured, and four magnetoresistance effect elements 122a to 122c and 123.

The feedback coil 121 is configured using a planar coil. Since the configuration does not have a magnetic core, it may be possible to manufacture the feedback coil at low cost. In addition, as compared with a case of a toroidal coil, it may be possible to prevent the cancelling magnetic field, which is generated from the feedback coil, from extensively spreading, and to prevent it from influencing a peripheral circuit. Furthermore, as compared with the case of the toroidal coil, if the current to be measured is an alternating current, the control of the cancelling magnetic field by the feedback coil is easy, and a current flowing for the control is not particularly increased. These effects become greater as the current to be measured, which is an alternating current, becomes a high frequency. In the case where the feedback coil 121 is configured using the planar coil, it is desirable that the planar coil is provided so that both the induction magnetic field and the cancelling magnetic field are generated in a plane parallel to the forming surface of the planar coil.

The resistance values of the magnetoresistance effect elements 122a to 122c and 123 change owing to the application of the induction magnetic field from the current I to be measured. The four magnetoresistance effect elements 122a to 122c and 123 configure a magnetic field detection bridge circuit. It may be possible to realize a highly-sensitive magnetic balance type current sensor using the magnetic field detection bridge circuit including the magnetoresistance effect element in this way.

The magnetic field detection bridge circuit includes two outputs for causing a voltage difference according to the induction magnetic field generated owing to the current I to be measured. In the magnetic field detection bridge circuit illustrated in FIG. 2, a power source Vdd is connected to a connection point between the magnetoresistance effect element 122b and the magnetoresistance effect element 122c, and a ground (GND) is connected to a connection point between the magnetoresistance effect element 122a and the magnetoresistance effect element 123. Furthermore, in the magnetic field detection bridge circuit, one output (OUT1) is taken from a connection point between the magnetoresistance effect element 122a and the magnetoresistance effect element 122b, and the other output (OUT2) is taken from a connection point between the magnetoresistance effect element 122c and the magnetoresistance effect element 123. These two outputs are amplified by an amplifier 124, and then are applied to the feedback coil 121 as a current (feedback current). The feedback current corresponds to a voltage difference according to the induction magnetic field. At this time, the cancelling magnetic field for cancelling out the induction magnetic field is generated in the feedback coil 121. In addition, the current to be measured is measured by a detection unit (detection resistor R) on the basis of the current flowing in the feedback coil 121 when an equilibrium state where the induction magnetic field and the cancelling magnetic field cancel each other out has occurred.

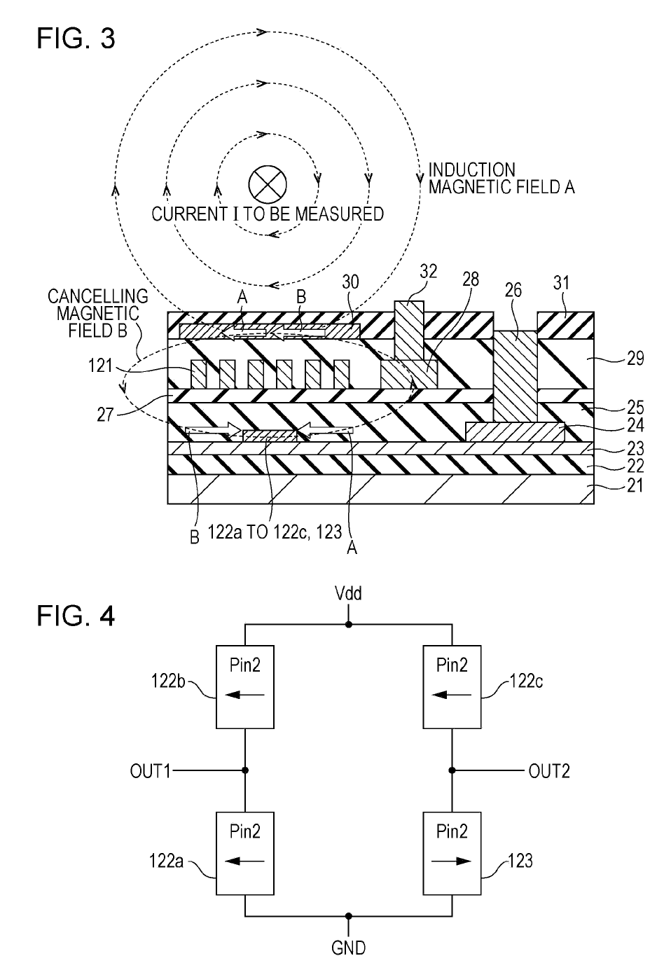

FIG. 3 is a cross-sectional view illustrating the magnetic balance type current sensor illustrated in FIG. 1. As illustrated in FIG. 3, in the magnetic balance type current sensor according to the present embodiment, the feedback coil, the magnetic shield, and the magnetic field detection bridge circuit are formed on a same substrate 21. In the configuration illustrated in FIG. 3, the feedback coil is disposed between the magnetic shield and the magnetic field detection bridge circuit, and the magnetic shield is disposed on a side near the current I to be measured. Namely, the magnetic shield, the feedback coil, and the magnetoresistance effect element are disposed in this order from a side near the conductor 11. Accordingly, it may be possible to cause the magnetoresistance effect element to be farthest away from the conductor 11, and it may be possible to reduce the induction magnetic field applied to the magnetoresistance effect element from the current I to be measured. In addition, since it may be possible to cause the magnetic shield to be nearest to the conductor 11, it may be possible to further improve the attenuation effect of the induction magnetic field. Accordingly, it may be possible to reduce the cancelling magnetic field from the feedback coil.

The layer configuration illustrated in FIG. 3 will be described in detail. In the magnetic balance type current sensor illustrated in FIG. 3, a thermal silicon oxide film 22 serving as an insulating layer is formed on the substrate 21. An aluminum oxide film 23 is formed on the thermal silicon oxide film 22. For example, it may be possible to form the aluminum oxide film 23 as a film by a method such as sputtering. In addition, a silicon substrate or the like is used as the substrate 21.

The magnetoresistance effect elements 122a to 122c and 123 are formed on the aluminum oxide film 23 to form a magnetic field detection bridge circuit. As the magnetoresistance effect elements 122a to 122c and 123, a TMR element (tunnel-type magnetoresistance effect element), a GMR element (giant magnetoresistance effect element), or the like may be used. The film configuration of the magnetoresistance effect element used in the magnetic balance type current sensor according to the present invention will be described below.

As the magnetoresistance effect element, as illustrated in the enlarged view of FIG. 2, a GMR element having a shape (meander shape) is desirable, in which a plurality of belt-like elongated patterns (stripes), disposed so that the longitudinal directions thereof are parallel to one another, are folded. In the meander shape, a sensitivity axis direction (Pin direction) is a direction (stripe width direction) perpendicular to the longitudinal direction (stripe longitudinal direction) of the elongated pattern. In the meander shape, the induction magnetic field and the cancelling magnetic field are applied so as to be headed in a direction (stripe width direction) perpendicular to the stripe longitudinal direction.

Considering linearity in the meander shape, it is desirable that the width of the meander shape in a Pin direction is 1 μm to 10 μm. In this case, considering the linearity, it is desirable that the longitudinal direction is perpendicular to both the direction of the induction magnetic field and the direction of the cancelling magnetic field. By adopting such a meander shape, it may be possible to obtain the output of the magnetoresistance effect element with fewer terminals (two terminals) than Hall elements.

In addition, an electrode 24 is formed on the aluminum oxide film 23. The electrode 24 may be formed by photolithography and etching after an electrode material has been formed as a film.

On the aluminum oxide film 23 in which the magnetoresistance effect elements 122a to 122c and 123 and the electrode 24 are formed, a polyimide layer 25 is formed as an insulating layer. The polyimide layer 25 may be formed by applying and curing a polyimide material.

A silicon oxide film 27 is formed on the polyimide layer 25. For example, the silicon oxide film 27 may be formed as a film using a method such as sputtering.

The feedback coil 121 is formed on the silicon oxide film 27. The feedback coil 121 may be formed by photolithography and etching after a coil material has been formed as a film. Alternatively, the feedback coil 121 may be formed by photolithography and plating after a base material has been formed as a film.

In addition, a coil electrode 28 is formed on the silicon oxide film 27 in the vicinity of the feedback coil 121. The coil electrode 28 may be formed by photolithography and etching after an electrode material has been formed as a film.

On the silicon oxide film 27 on which the feedback coil 121 and the coil electrode 28 are formed, a polyimide layer 29 is formed as an insulating layer. The polyimide layer 29 may be formed by applying and curing a polyimide material.

A magnetic shield 30 is formed on the polyimide layer 29. As the configuration material of the magnetic shield 30, a high magnetic permeability material such as an amorphous magnetic material, a permalloy-based magnetic material, or an iron-based microcrystalline material may be used.

A silicon oxide film 31 is formed on the polyimide layer 29. The silicon oxide film 31 may be formed as a film using a method such as, for example, sputtering. Contact holes are formed in predetermined regions of the polyimide layer 29 and the silicon oxide film 31 (a region of the coil electrode 28 and a region of the electrode 24), and electrode pads 32 and 26 are formed in the respective contact holes. The contact holes are formed using photolithography and etching, or the like. The electrode pads 32 and 26 may be formed by photolithography and plating after an electrode material has been formed as a film.

In the magnetic balance type current sensor including such a configuration as described above, as illustrated in FIG. 3, the magnetoresistance effect element receives the induction magnetic field A generated from the current I to be measured, and then the induction magnetic field is fed back to generate the cancelling magnetic field B from the feedback coil 121. In addition to this, two magnetic fields (the induction magnetic field A and the cancelling magnetic field B) are appropriately adjusted in such a way that the magnetic fields are cancelled out, thereby causing a magnetizing field applied to the magnetoresistance effect element 121 to be zero.

The magnetic balance type current sensor of the present invention includes the magnetic shield 30 adjacent to the feedback coil 121, as illustrated in FIG. 3. It may be possible for the magnetic shield 30 to attenuate the induction magnetic field, generated from the current I to be measured and applied to the magnetoresistance effect element (the direction of the induction magnetic field A and the direction of the cancelling magnetic field B are directions opposite to each other in the magnetoresistance effect element), and enhance the cancelling magnetic field B from the feedback coil 121 (the direction of the induction magnetic field A and the direction of the cancelling magnetic field B are the same direction in the magnetic shield). Accordingly, since the magnetic shield 30 functions as a magnetic yoke, it may be possible to reduce the current flowing in the feedback coil 121 and achieve electric power saving. In addition, it may be possible to reduce the influence of the external magnetic field owing to the magnetic shield 30.

The magnetic balance type current sensor including such a configuration as described above utilizes the magnetic field detection bridge circuit including, as the magnetic detecting element, the magnetoresistance effect element, in particular, the GMR element or the TMR element. Accordingly, it may be possible to realize a highly-sensitive magnetic balance type current sensor. In addition, in the magnetic balance type current sensor, since the magnetic detecting bridge circuit is configured using the four magnetoresistance effect elements whose film configurations are equal to one another, it may be possible to reduce a gap in a zero magnetizing field resistance value (R0) or a temperature coefficient resistivity (TCR0) between elements. Therefore, it may be possible to reduce a variation in a midpoint potential independently of an ambient temperature and perform current measurement with a high degree of accuracy. In addition, in the magnetic balance type current sensor including the above-mentioned configuration, since the feedback coil 121, the magnetic shield 30, and the magnetic field detection bridge circuit are formed on the same substrate, it may be possible to achieve downsizing. Furthermore, since the magnetic balance type current sensor does not include a magnetic core, it may be possible to achieve downsizing and cost reduction.

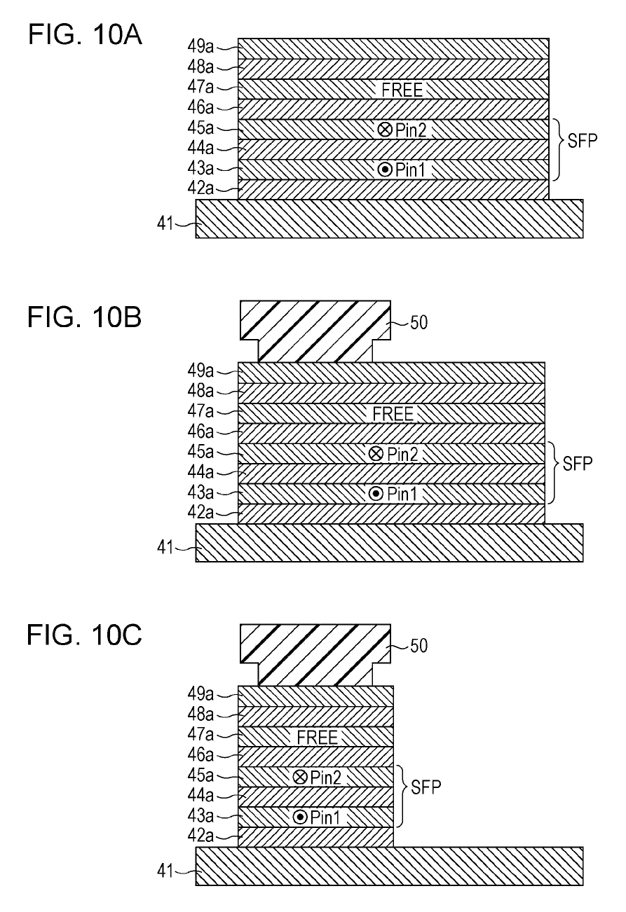

The film configuration of the magnetoresistance effect element used in the present invention is illustrated, for example, in FIG. 10A. Namely, the magnetoresistance effect element includes the laminate structure provided in the substrate 41, as illustrated in FIG. 10A. In addition, in FIG. 10A, for ease of explanation, a base layer and the like other than the magnetoresistance effect element are omitted in the substrate 41, and illustration is performed. The magnetoresistance effect element includes a seed layer 42a, a first ferromagnetic film 43a, an antiparallel coupling film 44a, a second ferromagnetic film 45a, a non-magnetic intermediate layer 46a, soft magnetic free layers (free magnetic layers) 47a and 48a, and a protective layer 49a.

The seed layer 42a is formed using NiFeCr, Cr, or the like. The protective layer 49a is formed using Ta or the like. In addition, in the above-mentioned laminate structure, a base layer formed using a non-magnetic material, such as at least one element of, for example, Ta, Hf, Nb, Zr, Ti, Mo, and W, may be provided between the substrate 41 and the seed layer 42a.

In the magnetoresistance effect element, the first ferromagnetic film 43a and the second ferromagnetic film 45a are antiferromagnetically coupled to each other via the antiparallel coupling film 44a therebetween, thereby configuring a so-called self-pinned type ferromagnetic fixed layer (SFP: Synthetic Ferri Pinned layer).

In the ferromagnetic fixed layer, the thickness of the antiparallel coupling film 44a is set to 0.3 nm to 0.45 nm, or 0.75 nm to 0.95 nm, and hence, it may be possible to achieve a strong antiferromagnetic coupling between the first ferromagnetic film 43a and the second ferromagnetic film 45a.

In addition, the magnetization amount (Ms·t) of the first ferromagnetic film 43a and the magnetization amount (Ms·t) of the second ferromagnetic film 45a are substantially equal to each other. Namely, a difference in magnetization amount between the first ferromagnetic film 43a and the second ferromagnetic film 45a is substantially zero. Therefore, the effective anisotropic magnetic field of the SFP layer is large. Accordingly, even if an antiferromagnetic material is not used, it may be possible to sufficiently ensure the magnetization stability of the ferromagnetic fixed layer (Pin layer). This is because when it is assumed that the film thickness of the first ferromagnetic film is t1, the film thickness of the second ferromagnetic film is t2, and magnetization and an induced magnetic anisotropic constant per unit volume of both layers are Ms and K, respectively, the effective anisotropic magnetic field of the SFP layer is represented by the following Expression (1).

effHk=2(K·t₁+K·t₂)/(Ms·t₁−Ms·t₂) Expression (1)

Accordingly, the magnetoresistance effect element used in the magnetic balance type current sensor of the present invention includes a film configuration with no antiferromagnetic layer.

A Curie temperature (Tc) of the first ferromagnetic film 43a and a Curie temperature (Tc) of the second ferromagnetic film 45a are approximately equal to each other. Accordingly, a difference in magnetization amount (Ms·t) between the two films 43a and 45a under a high-temperature environment also becomes about zero, and hence, it may be possible to maintain the high magnetization stability.

It is desirable that the first ferromagnetic film 43a is formed using CoFe alloy containing Fe of 40 atomic percent to 80 atomic percent. The reason is that the CoFe alloy of the composition range has a high coercive force, and may reliably maintain the magnetization with respect to the external magnetizing field. In addition, it is desirable that the second ferromagnetic film 45a is formed using CoFe alloy containing Fe of 0 atomic percent to 40 atomic percent. The reason is that the CoFe alloy of the composition range has a low coercive force, and may be easily magnetized in a direction antiparallel to (direction different by 180 degrees from) a direction in which the first ferromagnetic film 43a is preferentially magnetized. As a result, it may be possible to further increase Hk indicated by the Expression (1). In addition, by limiting the second ferromagnetic film 45a to this composition range, it may be possible to increase the resistance change rate of the magnetoresistance effect element.

It is desirable that, in the first ferromagnetic film 43a and the second ferromagnetic film 45a, a magnetizing field is applied in the stripe width direction of the meander shape during the film formation thereof and induced magnetic anisotropy is added to the first ferromagnetic film 43a and the second ferromagnetic film 45a after the film formation. Accordingly, both the films 43a and 45a are magnetized antiparallel to the stripe width direction. In addition, since the magnetization directions of the first ferromagnetic film 43a and the second ferromagnetic film 45a are determined by the application direction of a magnetizing field at the time of the film formation of the first ferromagnetic film 43a, it may be possible to form a plurality of magnetoresistance effect elements having ferromagnetic fixed layers whose magnetization directions are different from one another, on the same substrate by changing the application direction of the magnetizing field at the time of the film formation of the first ferromagnetic film 43a.

The antiparallel coupling film 44a in a ferromagnetic fixed layer is formed using Ru or the like. In addition, the soft magnetic free layers (free layers) 47a and 48a are formed using a magnetic material such as a CoFe alloy, a NiFe alloy, or a CoFeNi alloy. In addition, the non-magnetic intermediate layer 46a is formed using Cu or the like. In addition, it is desirable that, in the soft magnetic free layers 47a and 48a, a magnetizing field is applied in the stripe longitudinal direction of the meander shape during the film formation thereof and induced magnetic anisotropy is added to the soft magnetic free layers 47a and 48a after the film formation. Accordingly, in the magnetoresistance effect element, resistance linearly changes with respect to an external magnetizing field (magnetizing field from a current to be measured) in the stripe width direction, and it may be possible to reduce hysteresis. In such a magnetoresistance effect element, owing to the ferromagnetic fixed layer, the non-magnetic intermediate layer, and the soft magnetic free layer, a spin-valve configuration is adopted.

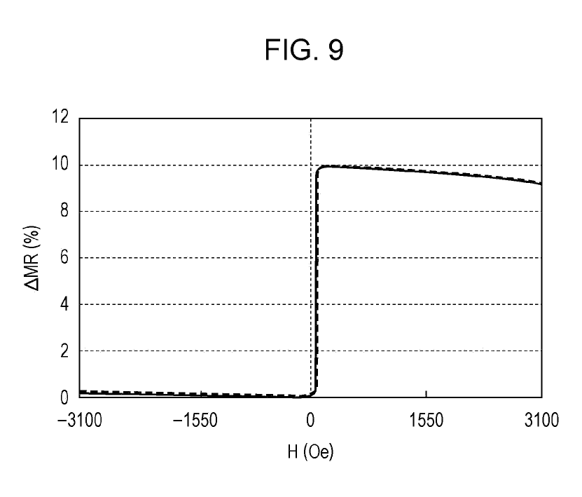

An example of the film configuration of the magnetoresistance effect element used in the magnetic balance type current sensor of the present invention includes, for example, NiFeCr (seed layer: 5 nm), Fe70Co30 (first ferromagnetic film: 1.65 nm), Ru (antiparallel coupling film: 0.4 nm), Co90Fe10 (second ferromagnetic film: 2 nm), Cu (non-magnetic intermediate layer: 2.2 nm), Co90Fe10 (soft magnetic free layer: 1 nm), NiFe (soft magnetic free layer: 7 nm), and Ta (protective layer: 5 nm). When an R-H waveform was studied with respect to the magnetoresistance effect element of such a film configuration, such a result as illustrated in FIG. 9 was obtained and it was understood that the same characteristic as the R-H waveform of a magnetoresistance effect element of a type that fixes the magnetization of a fixed magnetic layer using an antiferromagnetic film was obtained. In addition, the R-H waveform illustrated in FIG. 9 was obtained under the condition of normal measurement.

In the magnetic balance type current sensor of the present invention, as illustrated in FIG. 4, the magnetization directions of the ferromagnetic fixed layers of the three magnetoresistance effect elements 122a to 122c (the magnetization direction of the second ferromagnetic film: Pin2) from among the four magnetoresistance effect elements 122a to 122c and 123 are equal to one another, and the magnetization direction of the ferromagnetic fixed layer of the remaining one magnetoresistance effect element 123 (the magnetization direction of the second ferromagnetic film: Pin2) is a direction different by 180 degrees from the magnetization directions of the ferromagnetic fixed layers of the three magnetoresistance effect elements 122a to 122c.

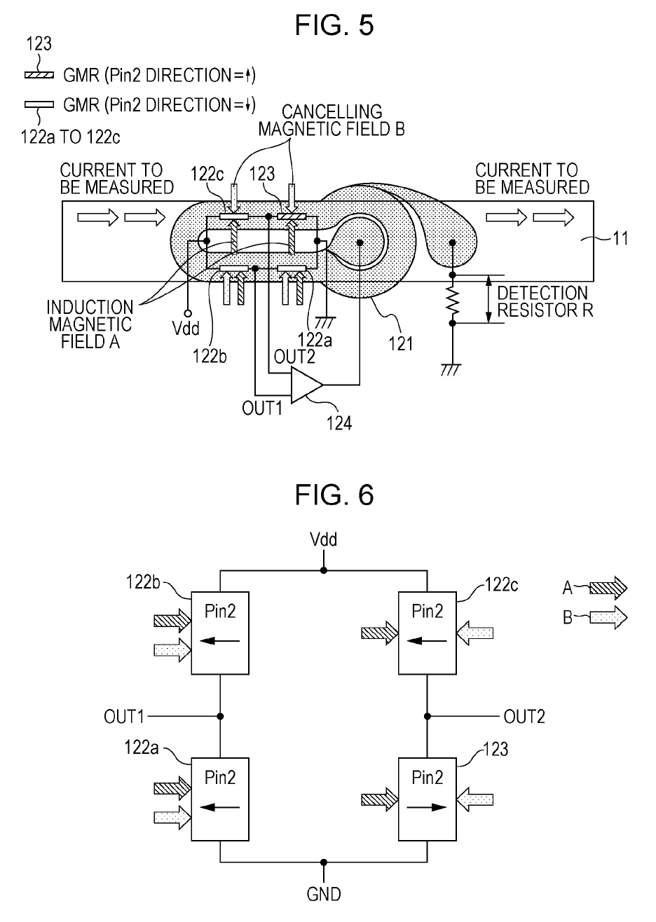

In the magnetic balance type current sensor including four magnetoresistance effect elements disposed in such a way as described above, the cancelling magnetic field is applied from the feedback coil 121 to the magnetoresistance effect element so that a voltage difference between the two outputs (OUT1 and OUT2) of the magnetic detecting bridge circuit becomes zero, and the current to be measured is measured by detecting the value of a current flowing in the feedback coil 121 at that time. As illustrated in FIG. 5, if the current to be measured flows from the observers' left side of the plane of paper in FIG. 5, the induction magnetic field A and the cancelling magnetic field B are applied to the two magnetoresistance effect elements 122a and 122b (on the OUT1 side) in a same direction, as illustrated in FIG. 6.

Since the magnetization directions of the ferromagnetic fixed layers of the two magnetoresistance effect elements 122a and 122b are equal to each other independently of the intensities of the induction magnetic field A and the cancelling magnetic field B, the resistance values of the magnetoresistance effect elements 122a and 122b constantly indicate a same value. Accordingly, the output of the OUT1 is constantly a fixed value (Vdd/2). Therefore, the magnetoresistance effect elements 122a and 122b play the same roles as fixed resistance elements. On the other hand, since the magnetization directions of the ferromagnetic fixed layers of the two magnetoresistance effect elements 122c and 123 (on an OUT2 side) are antiparallel to each other, the resistances of the magnetoresistance effect elements 122c and 123 change in different directions in accordance with the intensity of the induction magnetic field A. However, since, at this time, the cancelling magnetic field B is arbitrarily applied so as to cancel out the induction magnetic field A, the magnetoresistance effect elements 122c and 123 indicate a same resistance value (Rc). Accordingly, the output of the OUT2 becomes Vdd/2, and a voltage difference between the two outputs becomes zero.

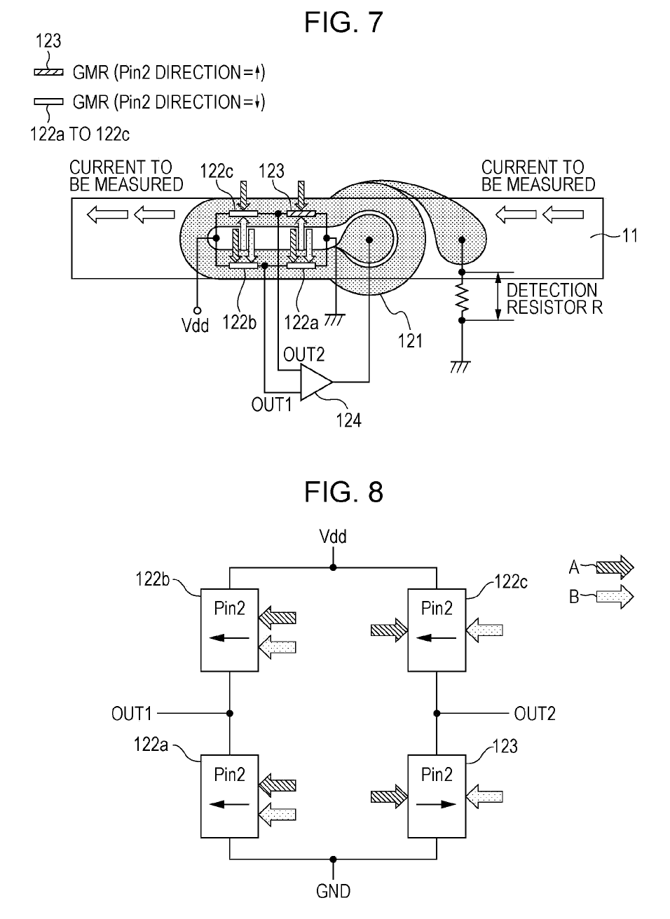

In addition, as illustrated in FIG. 7, if the current to be measured flows from the observers' right side of the plane of paper in FIG. 7, the induction magnetic field A and the cancelling magnetic field B are individually applied to the two magnetoresistance effect elements 122a and 122b (on the OUT1 side) and the two magnetoresistance effect elements 122c and 123 (on the OUT2 side), as illustrated in FIG. 8. An operating principle at this time is the same as described above.

In this way, in the magnetic balance type current sensor of the present invention, a magnetic detecting bridge circuit is configured using four magnetoresistance effect elements having a same film structure, and the magnetization direction of the first ferromagnetic film (second ferromagnetic film) of one magnetoresistance effect element is caused to be a direction antiparallel to the magnetization directions of the first ferromagnetic films (second ferromagnetic films) of the other three magnetoresistance effect elements. Therefore, it may be possible to cause the zero magnetizing field resistance values (R0) or temperature coefficient resistivities (TCR0) of the four magnetoresistance effect elements to coincide with one another, and it may be possible to realize a high-accuracy current sensor in which a midpoint potential does not vary owing to a temperature change.

It may also be possible to manufacture the magnetic balance type current sensor utilizing the four magnetoresistance effect elements, using a magnetoresistance effect element of a type that fixes the magnetization of a fixed magnetic layer owing to an antiferromagnetic film. In this case, so as to cause the exchange-coupling direction of the fixed magnetic layer (Pin layer) of one magnetoresistance effect element from among four magnetoresistance effect elements to be a direction antiparallel to the exchange-coupling directions of the fixed magnetic layers of the other three magnetoresistance effect elements, it may be necessary to apply laser local annealing or place a magnetic field applying coil adjacent to a magnetoresistance effect element. While such a method may be applied when a sensor or device is manufactured where a magnetoresistance effect element is located near a chip topmost surface, it is difficult to apply the method to the manufacture of a device where a thick organic insulation film, a thick feedback coil, and a thick magnetic shield film are placed on a magnetoresistance effect element in such a way as the magnetic balance type current sensor of the present invention. Therefore, in the magnetic balance type current sensor according to the present invention, the configuration of the present invention may be especially useful.

When a magnetic detecting bridge circuit and a feedback coil are integrally formed on a same substrate in the same way as the magnetic balance type current sensor according to the present invention, since it may be necessary to completely insulate the two from each other, the two are separated from each other using an organic insulation film such as a polyimide film. Usually the organic insulation film is formed by being subjected to heating treatment greater than or equal to 200° C. after application of spin coat or the like. Since the organic insulation film is formed in a post-process of the formation of the magnetic detecting bridge circuit, the magnetoresistance effect element is also heated together. In the manufacturing process of a magnetoresistance effect element of a type that fixes the magnetization of a fixed magnetic layer using an antiferromagnetic film, it may be necessary to perform heating treatment with applying a magnetizing field so that the characteristic of the fixed magnetic layer is not deteriorated owing to the thermal history of the formation process of the organic insulation film. In the magnetic balance type current sensor according to the present invention, since no antiferromagnetic film is used, it may be possible to maintain the characteristic of the fixed magnetic layer even if the heating treatment is not performed with a magnetizing field being applied. Accordingly, it may be possible to suppress the deterioration of the hysteresis of the soft magnetic free layer whose easy magnetization axis is perpendicular to a magnetizing field direction during the heating treatment.

In addition, when the magnetoresistance effect element of a type that fixes the magnetization of a fixed magnetic layer using an antiferromagnetic film is used, since the blocking temperature (a temperature at which an exchange-coupling magnetic field disappears) of an antiferromagnetic material is about 300° C. to 400° C., and the exchange-coupling magnetic field gradually decreases with drawing nigh to this temperature, the characteristic of the fixed magnetic layer becomes more unstable as a temperature becomes high. In the magnetic balance type current sensor according to the present invention, since no antiferromagnetic film is used, the characteristic of the fixed magnetic layer mainly depends on the Curie temperature of a ferromagnetic material configuring the fixed magnetic layer. In general, the Curie temperature of a ferromagnetic material such as CoFe is far higher than the blocking temperature of an antiferromagnetic material. Accordingly, by causing the Curie temperatures of the ferromagnetic materials of the first ferromagnetic film and the second ferromagnetic film to coincide with each other and keeping, at zero, a difference in magnetization amount (Ms·t) between the first ferromagnetic film and the second ferromagnetic film also in a high temperature region, it may be possible to maintain a high magnetization stability.

In addition, when the magnetoresistance effect element of a type that fixes the magnetization of a fixed magnetic layer using an antiferromagnetic film is used, it may be necessary to intentionally cause a difference between the magnetization amount (Ms·t) of the first ferromagnetic film and the magnetization amount (Ms·t) of the second ferromagnetic film, so as to generate the exchange-coupling magnetic field in the direction of an applied magnetizing field at the time of annealing. The reason is that when a difference in magnetization amount is zero, a magnetic field causing both the first ferromagnetic film and the second ferromagnetic film to be saturated exceeds a magnetizing field (to 15 kOe (×103/4π A/m)) capable of being applied at the time of annealing and as a result, the magnetization dispersion of the first ferromagnetic film and the second ferromagnetic film after annealing becomes large, thereby causing the deterioration of ΔR/R to occur. In addition, so as to increase ΔR/R, usually the film thickness of the second ferromagnetic film is caused to be thicker than the first ferromagnetic film (a magnetization amount is caused to be larger). Usually, when the magnetization amount of the second ferromagnetic film is larger than that of the first ferromagnetic film, a reflux magnetic field becomes large that is applied from the second ferromagnetic film to the soft magnetic free layer in an element side wall, and an influence on the asymmetry of an output becomes large. In addition, since this reflux magnetic field has a large temperature dependency, the temperature dependency of the asymmetry also becomes large. In the magnetic balance type current sensor according to the present invention, since a difference in magnetization amount between the first ferromagnetic film and the second ferromagnetic film in the magnetoresistance effect element is zero, it may also be possible to solve such a problem as described above.

In addition, since the magnetoresistance effect element of the magnetic balance type current sensor according to the present invention includes no antiferromagnetic material, it may also be possible to suppress a material cost or manufacturing cost.

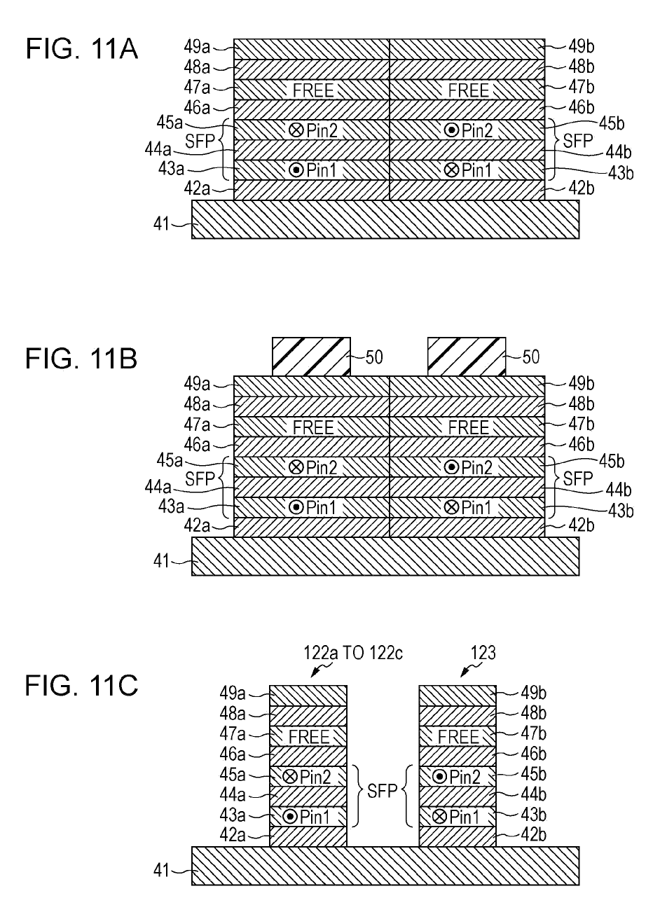

FIGS. 10A to 10C and FIGS. 11A to 11C are diagrams for explaining a manufacturing method for a magnetoresistance effect element in a magnetic balance type current sensor according to an embodiment of the present invention. First, as illustrated in FIG. 10A, on the substrate 41, the seed layer 42a, the first ferromagnetic film 43a, the antiparallel coupling film 44a, the second ferromagnetic film 45a, the non-magnetic intermediate layer 46a, the soft magnetic free layers (free magnetic layers) 47a and 48a, and the protective layer 49a are sequentially formed. During the film formation of the first ferromagnetic film 43a and the second ferromagnetic film 45a, a magnetizing field is applied in the stripe width direction of the meander shape. In FIGS. 10A to 10C, as for each of the first ferromagnetic film 43a and the second ferromagnetic film 45a, an applied-magnetizing field direction is a direction headed from the far side of the plane of paper to the near side thereof. After the film formation, the first ferromagnetic film 43a is preferentially magnetized in the applied-magnetizing field direction, and the second ferromagnetic film 45a is magnetized in a direction antiparallel to (direction different by 180 degrees from) the magnetization direction of the first ferromagnetic film 43a. In addition, during the film formation of the soft magnetic free layers (free magnetic layers) 47a and 48a, a magnetizing field is applied in the stripe longitudinal direction of the meander shape.

Next, as illustrated in FIG. 10B, a resist layer 50 is formed on the protective layer 49a, and owing to photolithography and etching, the resist layer 50 is caused to remain on a region on the magnetoresistance effect elements 122a to 122c side. Next, as illustrated in FIG. 10C, owing to ion milling or the like, an exposed laminated film is removed, and the substrate 41 in a region in which the magnetoresistance effect element 123 is to be provided is caused to be exposed.

Next, as illustrated in FIG. 11A, on the exposed substrate 41, a seed layer 42b, a first ferromagnetic film 43b, an antiparallel coupling film 44b, a second ferromagnetic film 45b, a non-magnetic intermediate layer 46b, soft magnetic free layers (free magnetic layers) 47b and 48b, and a protective layer 49b are sequentially formed. During the film formation of the first ferromagnetic film 43b and the second ferromagnetic film 45b, a magnetizing field is applied in the stripe width direction of the meander shape. In FIGS. 11A to 11C, as for each of the first ferromagnetic film 43b and the second ferromagnetic film 45b, an applied-magnetizing field direction is a direction headed from the near side of the plane of paper to the far side thereof. On the basis of the same as the above-mentioned principle, the first ferromagnetic film 43b and the second ferromagnetic film 45b are magnetized in directions antiparallel to (directions different by 180 degrees from) each other. In addition, during the film formation of the soft magnetic free layers (free magnetic layers) 47b and 48b, a magnetizing field is applied in the stripe longitudinal direction of the meander shape.

Next, as illustrated in FIG. 11B, the resist layer 50 is formed on the protective layers 49a and 49b, and owing to photolithography and etching, the resist layer 50 is caused to remain on the forming regions of the magnetoresistance effect elements 122a to 122c and 123. Next, as illustrated in FIG. 11C, owing to ion milling or the like, an exposed laminated film is removed, and the magnetoresistance effect elements 122a to 122c and 123 are formed.

In this way, according to the magnetic balance type current sensor of the present invention, since the magnetic detecting bridge circuit is configured using the four magnetoresistance effect elements whose film configurations are equal to one another, it may be possible to reduce a gap in a zero magnetizing field resistance value (R0) or a temperature coefficient resistivity (TCR0) between elements. Therefore, it may be possible to reduce a variation in a midpoint potential independently of an ambient temperature and perform current measurement with a high degree of accuracy.

The present invention is not limited to the above-mentioned embodiments, and may be implemented with being variously modified. For example, the material, the connection relationship of each element, the thickness, the size, and the manufacturing method in the above-mentioned embodiments may be implemented with being arbitrarily modified. In addition, the present invention may be implemented with being variously modified and without departing from the scope of the invention.

The present invention may be applied to a current sensor for detecting the intensity of a current used for driving a motor of an electric vehicle.

What is claimed is:

1. A magnetic balance type current sensor comprising:
a magnetic field detection bridge circuit configured to include four magnetoresistance effect elements whose resistance values change owing to application of an induction magnetic field from a current to be measured and provide two outputs for causing a voltage difference according to the induction magnetic field; a feedback coil configured to be disposed near the magnetoresistance effect element and generate a cancelling magnetic field for cancelling out the induction magnetic field; and a magnetic shield configured to attenuate the induction magnetic field and enhance the cancelling magnetic field, wherein
the current to be measured is measured on the basis of a current flowing in the feedback coil when the feedback coil has been energized owing to the voltage difference and an equilibrium state where the induction magnetic field and the cancelling magnetic field cancel each other out has occurred, and
each of the four magnetoresistance effect elements includes a self-pinned type ferromagnetic fixed layer configured to be formed by causing a first ferromagnetic film and a second ferromagnetic film to be antiferromagnetically coupled to each other via an antiparallel coupling film, a non-magnetic intermediate layer, and a soft magnetic free layer, wherein the first ferromagnetic film and the second ferromagnetic film are approximately equal in Curie temperature to each other, a difference in magnetization amount therebetween is substantially zero, magnetization directions of the ferromagnetic fixed layers of three magnetoresistance effect elements from among the four magnetoresistance effect elements are equal to one another, and a magnetization direction of the ferromagnetic fixed layer of the remaining one magnetoresistance effect element is a direction different by 180 degrees from the magnetization directions of the ferromagnetic fixed layers of the three magnetoresistance effect elements.

2. The magnetic balance type current sensor according to claim 1, wherein
the feedback coil, the magnetic shield, and the magnetic field detection bridge circuit are formed on a same substrate.

3. The magnetic balance type current sensor according to claim 1, wherein
the feedback coil is disposed between the magnetic shield and the magnetic field detection bridge circuit, and the magnetic shield is disposed on a side near the current to be measured.

4. The magnetic balance type current sensor according to claim 1, wherein
each of the four magnetoresistance effect elements has a shape in which a plurality of belt-like elongated patterns, disposed so that longitudinal directions thereof are parallel to one another, are folded, and the induction magnetic field and the cancelling magnetic field are applied so as to be headed in a direction perpendicular to the longitudinal direction.

5. The magnetic balance type current sensor according to claim 1, wherein
the first ferromagnetic film is formed using CoFe alloy including Fe of 40 atomic percent to 80 atomic percent, and the second ferromagnetic film is formed using CoFe alloy including Fe of 0 atomic percent to 40 atomic percent.

6. The magnetic balance type current sensor according to claim 1, wherein
the magnetic shield is formed using a high magnetic permeability material selected from a group including an amorphous magnetic material, a permalloy-based magnetic material, and an iron-based microcrystalline material.
